(19) United States
(12) Patent Application Publication
(10) Pub. No.: US 2026/0201236 A1
(43) Pub. Date: Jul. 16, 2026

(54) SURFACE-MODIFIED CERAMIC PARTICLES AND HEAT DISSIPATING EPOXY RESIN COMPOSITION INCLUDING THE SAME

(71) Applicant: KOREA BASIC SCIENCE INSTITUTE, Daejeon (KR)

(72) Inventors: Gaehang LEE, Daejeon (KR); Yechan CHANG, Seoul (KR)

(21) Appl. No.: 19/368,464

(22) Filed: Oct. 24, 2025

(30) Foreign Application Priority Data
Jan. 15, 2025 (KR) 10-2025-0006114
Oct. 17, 2025 (KR) 10-2025-0150227

(51) Int. Cl. C09K 5/14; C08K 9/02; C09C 1/40; C09C 3/06; H10H 20/858

(52) U.S. Cl. CPC C09K 5/14; C08K 9/02; C09C 1/407; C09C 3/06; C01P 2002/54; C01P 2002/85; C01P 2004/03; C01P 2004/51; C01P 2004/61; C01P 2004/62; C01P 2004/86; C01P 2006/32; C08K 2201/001; C08K 2201/005; H10H 20/8581

(57) ABSTRACT

The present disclosure relates to a surface-modified ceramic particle including a ceramic particle and a modifying metal ion bonded to a surface of the ceramic particle. The present disclosure further relates to a heat dissipating epoxy resin composition including the surface-modified ceramic particles, and a heat dissipating cured product manufactured therefrom.

### CROSS REFERENCE TO RELATED APPLICATIONS

The present application claims priority to Republic of Korea Patent Application No. 10-2025-0006114 filed on Jan. 15, 2025, and to Republic of Korea Patent Application No. 10-2025-0150227 filed on Oct. 17, 2025. The entire contents of the above-listed applications are hereby incorporated by reference for all purposes.

### TECHNICAL FIELD

The present disclosure relates to a surface-modified ceramic particle whose surface is modified by a modifying metal ion, and a heat dissipating epoxy resin composition including the same.

### BACKGROUND ART

Currently, electronic devices are gradually trending toward miniaturization in use in high tech industries such as electronics, robotics, or automobiles. As the miniaturized electronic devices have a decreased total surface area, much heat energy generated is not easily released, and as a result, problems such as performance degradation and device damage due to accumulation of a large amount of heat generated arise.

Conventional electronic devices use an epoxy resin composition having effects of excellent heat resistance, excellent mechanical properties, and processability as an adhesive, but the conventional epoxy resin composition does not have thermal conductivity sufficient to dissipate heat generated in the miniaturized electronic devices.

Therefore, the conventional epoxy resin composition requires a new technology to have better heat dissipation.

In order to improve heat dissipation, the conventional epoxy resin composition includes heat dissipating particles such as ceramic-based particles, metal particles, and hydrocarbon-based particles.

However, since the conventional heat dissipating particles have low miscibility with an epoxy resin, it is difficult to include a large amount of the heat dissipating particles so as to have sufficient heat dissipating properties, while maintaining viscosity favorable for applicability, dimensional stability of a formed cured product, adhesion, mechanical strength, and the like.

That is, a complementary relationship between physical properties is encountered, in which when the conventional heat dissipating particles are included in a large amount in the epoxy resin composition, various physical properties of the epoxy resin composition described above are deteriorated, and when they are included in a small amount in order to maintain the various physical properties described above, the epoxy resin composition having sufficient heat dissipating properties which are currently required is not manufactured.

In order to solve the problem of low miscibility of the conventional heat dissipating particles with an epoxy resin, various technologies have been published, but thermal conductivity is not sufficiently satisfied. In addition, since the conventional heat dissipating particles have high manufacturing cost, marketability and economic feasibility are not still secured.

Accordingly, new heat dissipating particles which may be included in an excessive amount in an epoxy resin composition by solving the problem of low miscibility with the epoxy resin of the conventional heat dissipating particles are needed, and heat dissipating particles which may secure better economic feasibility by lowering production cost and a method for manufacturing the same are needed.

### DISCLOSURE

### Technical Problem

An object of the present disclosure is to provide a surface-modified ceramic particle in which modifying metal ions may be attached to the surface of a ceramic particle with excellent processability and excellent economic feasibility.

Another object of the present disclosure is to provide a surface-modified ceramic particle having excellent miscibility with an epoxy resin by an increased zeta potential.

Another object of the present disclosure is to provide a heat dissipating epoxy resin composition which may have excellent workability even with the inclusion of an excessive amount of the surface-modified ceramic particle.

Another object of the present disclosure is to provide a cured product having excellent dimensional stability, excellent mechanical strength, and high thermal conductivity simultaneously and a heat dissipating epoxy resin composition for manufacturing the same.

Still another object of the present disclosure is to provide an electronic device having an excellent heat dissipating effect, using the heat dissipating epoxy as a tackifying agent.

### Technical Solution

In one general aspect, a surface-modified ceramic particle includes: a ceramic particle and a modifying metal ion bonded to a surface of the ceramic particle.

As an exemplary embodiment of the present disclosure, the surface-modified ceramic particle may have a modifying metal bonded to the surface of the ceramic particle by a coordinate bond.

As an exemplary embodiment of the present disclosure, the surface-modified ceramic particles may have an average particle diameter (D50) of 0.1 to 100 μm.

As an exemplary embodiment of the present disclosure, the surface-modified ceramic particles may satisfy 0.1 μm≤average particle diameter (D50)<1.0 μm and may have a zeta potential measured in a suspension state at 1 mg/ml and pH 7 of 40.0 mV or more.

As an exemplary embodiment of the present disclosure, the surface-modified ceramic particles may satisfy 1.5 μm<average particle diameter (D50)≤100 μm and may have a zeta potential measured in a suspension state at 1 mg/ml and pH 7 of more than 38.0 mV.

As an exemplary embodiment of the present disclosure, the modifying metal ion may be any one or two or more cations selected from manganese (Mn), cobalt (Co), nickel (Ni), copper (Cu), iron (Fe), boron (B), and zirconium (Zr).

As an exemplary embodiment of the present disclosure, the modifying metal ion may be any one or two or more cations selected from iron (Fe), boron (B), and zirconium (Zr).

As an exemplary embodiment of the present disclosure, the ceramic particle may be an aluminum oxide particle.

As an exemplary embodiment of the present disclosure, the surface-modified ceramic particle may include 5 to 100 ppm of the modifying metal ion.

In another general aspect, a heat dissipating epoxy resin composition includes: an epoxy resin and the surface-modified ceramic particles.

As an exemplary embodiment of the present disclosure, the heat dissipating epoxy resin composition may include 10 to 800 parts by weight of the surface-modified ceramic particles with respect to 100 parts by weight of the epoxy resin.

As an exemplary embodiment of the present disclosure, the surface-modified ceramic particles may have a multimodal particle diameter distribution.

As an exemplary embodiment of the present disclosure, the surface-modified ceramic particles may have a bimodal particle diameter distribution.

As an exemplary embodiment of the present disclosure, the heat dissipating epoxy resin composition may have a viscosity measured at 25° C. and a shear rate of 1.0 s⁻¹ of 180 Pa·s or less, when 400 parts by weight of the surface-modified ceramic particles are included with respect to 100 parts by weight of the epoxy resin.

As an exemplary embodiment of the present disclosure, the heat dissipating epoxy resin composition may further include any one or more or two or more selected from metallic particles, carbonaceous particles, and carbon nitrides.

In another general aspect, a heat dissipating cured product manufactured by including the heat dissipating epoxy resin composition is provided.

As an exemplary embodiment of the present disclosure, the heat dissipating cured product may have a thermal conductivity measured at 25° C. of 1.310 W/m·K or more, when 400 parts by weight of the surface-modified ceramic particles are included with respect to 100 parts by weight of the epoxy resin.

As an exemplary embodiment of the present disclosure, the heat dissipating cured product may have a thermal conductivity measured at 25° C. of 1.400 W/m·K or more, when 400 parts by weight of the surface-modified ceramic particles are included with respect to 100 parts by weight of the epoxy resin.

As an exemplary embodiment of the present disclosure, the heat dissipating cured product may have a flexural modulus of 4.90 GPa or more, when 400 parts by weight of the surface-modified ceramic particles are included with respect to 100 parts by weight of the epoxy resin.

In another general aspect, an electronic device includes the heat dissipating cured product as an adhesive layer.

In still another general aspect, a method for manufacturing surface-modified ceramic particles includes: including a modifying metal ion precursor in the solvent to prepare a solution and including the solution and ceramic particles to manufacture surface-modified ceramic particles.

As an exemplary embodiment of the present disclosure, the modifying metal ion precursor may be any one or two or more selected from metal salts including manganese (Mn), titanium (Ti), silicon (Si), cobalt (Co), nickel (Ni), copper (Cu), iron (Fe), boron (B), or zirconium and metal salt hydrates thereof.

As an exemplary embodiment of the present disclosure, the modifying metal ion precursor may include any one or two or more modifying metal precursors selected from FeSO₄, B(OH)₃, ZrOCl₂, and hydrates thereof.

As an exemplary embodiment of the present disclosure, the manufacturing of surface-modified ceramic particles may be performed at a reaction temperature of 10 to 50° C.

As an exemplary embodiment of the present disclosure, the surface-modified ceramic particles may have a modification efficiency calculated by the following Equation 1 of 10% or more:

$$Modification efficiency ( \% ) = \frac{( {C}_{0} - {C}_{f} ) \times V}{m} \times 100 \qquad [ Equation 1 ]$$

wherein C₀ is an ion concentration (mg/L) of a modifying metal ion precursor in a solution, C_{f} is an ion concentration (mg/L) of a modifying metal ion precursor in a solution, after the manufacturing of surface-modified ceramic particles, V is a volume (V) of a solution, and m is a content (g) of ceramic particles added to the manufacturing of surface-modified ceramic particles.

As an exemplary embodiment of the present disclosure, the surface-modified ceramic particle may have a modification efficiency of 60% or more.

As an exemplary embodiment of the present disclosure, the solution may have a pH of 6 or more.

### Advantageous Effects

As an exemplary embodiment of the present disclosure, the method for manufacturing surface-modified ceramic particles allows manufacture of surface-modified ceramic particles at a low temperature of 50° C. or lower and may have excellent economic feasibility.

As an exemplary embodiment of the present disclosure, the method for manufacturing surface-modified ceramic particles may have a modification efficiency measured by the measuring method defined in the present disclosure of 10% or more, 15% or more, 20% or more, 50% or more, 60% or more, 70% or more, 80% or more, 90% or more, 95% or more, or 98% or more.

As an exemplary embodiment of the present disclosure, the heat dissipating epoxy resin composition may have a low viscosity of 180 Pa·s or less, 150 Pa·s or less, 100 Pa·s or less, 50 Pa·s or less, or 40 Pa·s or less at 25° C. and a heat dissipating of 1.0 s⁻¹, even with the inclusion of the surface-modified ceramic particles in an excessive amount of 400 parts by weight.

As an exemplary embodiment of the present disclosure, a heat dissipating cured product formed by the heat dissipating epoxy resin composition may have an excellent thermal conductivity under an environment of 25° C. of 1.300 W/m·K or more, 1.400 W/m·K or more, 1.500 W/m·K or more, 1.600 W/m. K or more, 1.700 W/m. K or more, or 1.800 W/m. K or more.

As an exemplary embodiment of the present disclosure, the heat dissipating cured product may have an excellent mechanical strength such as a flexural modulus measured by ASTM D790 of 4.90 GPa or more, 5.00 GPa or more, 5.50 GPa or more, or 6.00 GPa or more.

### DESCRIPTION OF DRAWINGS

FIG. 1A is a SEM/EDS photograph of alumina particles of Comparative Example 1. FIG. 1B is a SEM/EDS photograph of surface-modified ceramic particles of Example 1.

FIG. 2A-2D present X-ray Photoelectron Spectroscopy (XPS) analysis. FIG. 2A is XPS spectra of Fe—Al₂O₃ particles manufactured in Example 1 and r-Al₂O₃ particles manufactured in Comparative Example 1. FIG. 2B is high resolution XPS spectra of a Fe2p peak. FIG. 2C is a high resolution XPS spectra of an O1s peak of r-Al₂O₃ particles manufactured in Comparative Example 1. FIG. 2D is a high resolution XPS spectra of an O1s peak of Fe—Al₂O₃ particles manufactured in Example 1.

FIG. 3 shows results of measuring coefficients of thermal expansion of cured products of Example 14, Example 26, and Comparative Example 3.

### BEST MODE

Technical terms and scientific terms described in the present disclosure have the general meaning understood by a person with ordinary skill in the art to which the present disclosure pertains unless otherwise defined, and description of the known function and configuration obscuring the present disclosure will be omitted in the following description.

In addition, the singular form used in the present disclosure may be intended to also include a plural form, unless otherwise indicated in the context.

In addition, units used in the present disclosure without particular mention are based on weights, and as an example, a unit of % or ratio refers to a wt % or a weight ratio, and wt % refers to wt % of any one component in a total composition, unless otherwise defined.

In addition, the numerical range used in the present disclosure includes all values within the range including the lower limit and the upper limit, increments logically derived in a form and span of a defined range, all double limited values, and all possible combinations of the upper limit and the lower limit in the numerical range defined in different forms.

Unless otherwise defined in the specification of the present disclosure, values which may be outside a numerical range due to experimental error or rounding off of a value are also included in the defined numerical range.

The term “comprise” in the present disclosure is an open-ended description having a meaning equivalent to the term such as “is/are provided”, “contain”, “have”, or “is/are characterized”, and does not exclude elements, materials, or processes which are not further listed.

The term “C1-Cn” of the present disclosure may refer to a hydrocarbon having 1 to n carbon atoms.

There is a technology of further including heat dissipating particles such as ceramic-based particles and/or metallic particles in an epoxy resin used in conventional electronic devices in order to improve heat dissipating properties. However, conventional heat dissipating particles may not be included in a large amount due to low miscibility with an epoxy resin, and even when the conventional heat dissipating particles are included in a large amount, physical properties such as viscosity, curing behavior, dimensional stability, adhesion on a substrate, and mechanical strength are deteriorated.

In order to solve the problem of low miscibility of the conventional heat dissipating particles with an epoxy resin described above, the present disclosure provides a surface-modified ceramic particle in which a modifying metal ion is bonded to the surface of a ceramic particle, and a heat dissipating epoxy resin composition having both low viscosity and excellent heat dissipating properties by including the surface-modified ceramic particles.

In addition, the present disclosure provides a method for manufacturing surface-modified ceramic particles having excellent surface modification even with a low process temperature and excellent economic feasibility.

Hereinafter, each of the above constituent components and the disclosure will be described in detail.

### [Surface-Modified Ceramic Particle]

The present disclosure provides a surface-modified ceramic particles including: a ceramic particle and a modifying metal ion bonded to a surface of the ceramic particle.

Since the surface-modified ceramic particle includes a modifying metal ion bonded to the surface to have an increased zeta potential, and as a result, may have excellent miscibility with an epoxy resin, even when the particles are included in an excessive amount, a heat dissipating epoxy resin composition having viscosity favorable for workability and heat dissipating properties simultaneously may be provided.

As an exemplary embodiment of the present disclosure, the surface-modified ceramic particle may have a modifying metal ion bonded to the surface of the ceramic particle by adsorption and a coordinate bond or may be bonded by a coordinate bond.

In the surface-modified ceramic particle, since the modifying metal ion is uniformly adsorbed on the surface of the ceramic particle and included, the particles may have a high zeta potential, and as a result, may have excellent miscibility with an epoxy resin.

As an exemplary embodiment of the present disclosure, the ceramic particle may be a collective term of ceramic particles or inorganic particles which may be used in the art, and as an example, may be alumina (Al₂O₃), aluminum nitride (AlN), silicon carbide (SiC), silica (SiO₂), zirconia (ZrO₂), and the like, and optionally alumina (Al₂O₃) alone.

The alumina particles have a low unit price as compared with ceramic particles used in the art and are excellently bonded to the modifying metal ion, and the surface-modified alumina particles manufactured by including the alumina particles may have excellent surface modification.

As an exemplary embodiment of the present disclosure, the modifying metal ion may be any one or two or more cations selected from manganese (Mn), cobalt (Co), nickel (Ni), copper (Cu), iron (Fe), boron (B), zirconium (Zr), and the like, optionally any one or two or more selected from iron (Fe), boron (B), zirconium (Zr), and the like, and optionally iron (Fe), boron (B), and zirconium alone.

The surface-modified ceramic particle has a higher zeta potential when the modifying metal ion of iron (Fe), boron (B), and zirconium (Zr) is bonded to the surface, and may be preferred since a heat dissipating epoxy resin composition including the particles may have low viscosity and high thermal conductivity simultaneously.

As an exemplary embodiment of the present disclosure, the surface-modified ceramic particles may have an average particle diameter (D50) of 0.1 μm or more, 0.5 μm or more, 1.0 μm or more, 1.5 μm or more, 2.0 μm or more, 5.0 μm or more, 10.0 μm or more, 15.0 μm or more, 20.0 μm or more and 100.0 μm or less, 90.0 μm or less, 80.0 μm or less, 70.0 μm or less, 60.0 μm or less, or 50.0 μm or less, and may also be a value within the ranges of the above figures. For example, the average particle diameter may be 0.1 to 100.0 μm, 0.1 to 90.0 μm, 0.1 to 80.0 μm, 0.1 to 70.0 μm, 0.1 to 60.0 μm, 0.1 to 50.0 μm, 0.5 to 50.0 μm, 1.0 to 50.0 μm, 1.5 to 50.0 μm, 2.0 to 50.0 μm, or 5.0 to 50.0 μm.

Since the surface-modified ceramic particles having the average particle diameter in the above range may have an increased zeta potential as compared with the ceramic particles before surface modification and may have excellent miscibility with an epoxy resin, they may be preferred, but they are not necessarily limited thereto as long as the physical properties are not impaired.

In addition, the surface-modified ceramic particles may have the average particle diameter (D50) which is not greatly increased as compared with the ceramic particles before surface modification, and as a non-limiting example, when the average particle diameter of the ceramic particles before surface modification is 100%, the average particle diameter of the surface-modified ceramic particles may be increased by 2% or less, 1.5% or less, 1.0% or less, or 0.5% or less, and though the lower limit is not limited, may be increased by 0.1% or more.

The average particle diameter (D50) of the surface-modified ceramic particles may be measured using laser scattering particle size analysis (PSA, Sympatec GmbH, HELOS series), and “Dn” (n is a real number) refers to a diameter of a particle corresponding to n vol % in a volume-based integrated fraction. For example, “D50” may refer to a diameter of a particle corresponding to 50 vol % in a volume-based integrated fraction, and this may be defined as the average particle diameter (D50).

As an exemplary embodiment of the present disclosure, the surface-modified ceramic particles may have a multimodal particle diameter distribution or a bimodal particle diameter distribution, which is measured by the measurement method described later.

The surface-modified ceramic particles having the multimodal particle diameter distribution may further lower the viscosity of the heat dissipating epoxy resin composition prepared by including the surface-modified ceramic particles, may provide a cured product having higher thermal conductivity and higher mechanical strength.

As an example, when the surface-modified ceramic particles have the bimodal particle diameter distribution, a mode ratio between a first surface-modified ceramic particle and a second surface-modified ceramic particle may be 1:1.5 to 1:10, 1:2 to 1:8, 1:2 to 1:6, or 1:3 to 1:5.

When the heat dissipating epoxy resin composition includes the surface-modified ceramic particles having the bimodal particle diameter distribution with the mode at the ratio described above, it may have low viscosity, and a cured product having better mechanical strength may be prepared by including the composition, but the present disclosure is not necessarily limited thereto as long as the physical properties are not impaired.

As an exemplary embodiment of the present disclosure, the surface-modified ceramic particles may have a modifying metal ion content of 5.0 ppm or more, 6.0 ppm or more, 7.0 ppm or more, 8.0 ppm or more, 9.0 ppm or more, 10.0 ppm or more, 15.0 ppm or more, 20.0 ppm or more, 25.0 ppm or more, 30.0 ppm or more, 35.0 ppm or more, or 40.0 ppm or more, and though the upper limit is not limited, 100.0 ppm or less, 80.0 ppm or less, or 60.0 ppm or less, with respect to the total weight. For example, the modifying metal ion content may be 5.0 to 100.0 ppm, 6.0 to 100.0 ppm, 7.0 to 100.0 ppm, 8.0 to 100.0 ppm, 9.0 to 100.0 ppm, 10.0 to 100.0 ppm, 15.0 to 100.0 ppm, 20.0 to 100.0 ppm, 25.0 to 100.0 ppm, 30.0 to 100.0 ppm, 35.0 to 100.0 ppm, 35 to 80 ppm, 35 to 60.0 ppm, or 40 to 60.0 ppm.

The surface-modified ceramic particles include the modifying metal ion at the content in the range described above to increase a zeta potential to have excellent miscibility with an epoxy resin.

As an exemplary embodiment of the present disclosure, since the surface-modified ceramic particles may not further include an ion added in the manufacture in addition to the modifying metal ion described above, deterioration of physical properties due to the additional inclusion of other ions may be prevented.

As an example, the surface-modified ceramic particles may include 100 ppm or less, 50 ppm or less, 10 ppm or less, 5 ppm or less, 1 ppm or less, 0.5 ppm or less, 0.2 ppm or less, 0.1 ppm or less of a sulfur ion, with respect to the total mass.

The surface-modified ceramic particles may be measured with inductively coupled plasma (ICP), and since this is described in the following examples in detail, additional description will be omitted.

As an exemplary embodiment of the present disclosure, the surface-modified ceramic particles may have the zeta potential of 38 mV or more, 39.0 mV or more, 40.0 mV or more, 41.0 mV or more, 42.0 mV or more, 43.0 mV or more, 44.0 mV or more, 45.0 mV or more, 46.0 mV or more, 47.0 mV or more, or 60.0 mV or less.

The surface-modified ceramic particles may have a higher zeta potential than the ceramic particles which is not surface-modified, by having a modifying metal ion bonded to the surface of the ceramic particle, and thus, may have better miscibility with an epoxy resin. As a result, the heat dissipating epoxy resin composition including the surface-modified ceramic particles may maintain viscosity favorable for workability and produce a cured product having a high thermal conductivity, even with the inclusion of an excessive amount of surface-modified ceramic particles.

Since the ceramic particles have different surface curvature and structural forms of a hydroxyl group (*—OH) depending on the average particle diameter (D50), the zeta potential may vary depending on the average particle diameter, and as an example, there is an aspect in which as the average particle diameter (D50) increases, the zeta potential decreases.

However, the surface-modified ceramic particles may have an increased zeta potential value as compared with the zeta potential value according to the average particle diameter (D50) of the ceramic particles, by the surface modification of the ceramic particles, and as an exemplary embodiment, may be as follows.

As an exemplary embodiment of the present disclosure, the particles may satisfy 1.5 μm<average particle diameter (D50)≤100 μm, and the zeta potential measured in a suspension state of 1 mg/ml and pH 7 may be more than 38.0 mV, 39 mV or more, 40.0 mV or more, 41.0 mV or more, 42.0 mV or more, 43.0 mV or more, 44.0 mV or more, 45.0 mV or more, 46.0 mV or more, or 50.0 mV or less.

In addition, as an exemplary embodiment of the present disclosure, the particles may satisfy 0.1 μm<average particle diameter (D50)≤1.0 μm, and the zeta potential measured in a suspension state of 1 mg/ml and pH 7 may be more than 40.0 mV or more, 41.0 mV or more, 41.2 mV or more, 43.0 mV or more, 44.0 mV or more, 45.0 mV or more, 46.0 mV or more, 47.0 mV or more, 48.0 mV or more, 49.0 mV or more, 50.0 mV or more, or 60.0 mV or more.

The surface-modified ceramic particles may have a higher zeta potential as the average particle diameter (D50) is smaller, as described above, but may have a higher zeta potential as compared with the ceramic particles having the same average particle diameter (D50).

That is, the heat dissipating epoxy resin composition may include ceramic particles having an optimal average particle diameter, depending on the viscosity and the mechanical strength and thermal conductivity of the heat dissipating cured product formed therefrom. Since the surface-modified ceramic particles according to an exemplary embodiment of the present disclosure may have a higher zeta potential than the ceramic particles having the same average particle diameter (D50), the particles may have high thermal conductivity and low viscosity simultaneously by including them at a high content.

As an exemplary embodiment of the present disclosure, the zeta potential of the surface-modified ceramic particles may be 101% or more, 102% or more, 103% or more, 104% or more, 105% or more, 107% or more, 110% or more, 115% or more, or 120% or more, and though the upper limit is not limited, may be 200% or less or 150% or less, as compared with the zeta potential of the ceramic particles which are not surface-modified.

Hereinafter, the method for manufacturing the surface-modified ceramic particles will be described.

The method for manufacturing surface-modified ceramic particles of the present disclosure may include: including a modifying metal ion precursor in the solvent to prepare a solution, and including the solution and ceramic particles to manufacture surface-modified ceramic particles.

As an exemplary embodiment of the present disclosure, any modifying metal ion precursor may be used without limitation as long as it is soluble in water and may bond the modifying metal ion to the surface of the ceramic particle, and as an example, may be any one or two or more selected from metal salts including manganese (Mn), titanium (Ti), silicon (Si), cobalt (Co), nickel (Ni), copper (Cu), iron (Fe), boron (B), or zirconium, metal salt hydrates thereof, and the like. In addition, the modifying metal ion precursor may be a metal salt including iron (Fe), boron (B), or zirconium (Zr) or a metal salt hydrate thereof, in terms of the surface-modified ceramic particles manufactured by including the precursor having high zeta potential.

As an exemplary embodiment of the present disclosure, the modifying metal precursor may be any one or two selected from FeSO4, B(OH)₃, ZrOCl₂, hydrates thereof, and the like.

The method for manufacturing surface-modified ceramic particles may have different surface modification reactivity depending on the cation and anion of the used modifying metal ion precursor. The FeSO₄, B(OH)₃, ZrOCl₂, and hydrates thereof may be preferred as a specific example of the modifying metal ion precursor, since they allow the modifying metal ion to be bonded to the surface of an alumina particle well.

As an exemplary embodiment of the present disclosure, the manufacturing of surface-modified ceramic particles may be adding ceramic particles to a solution in which modifying metal ions are dissolved and stirring the solution at a reaction temperature of 10 to 50° C., and as another exemplary embodiment, may be stirring at a reaction temperature of 10 to 40° C., 10 to 30° C., or 15 to 30° C. In addition, the manufacturing of surface-modified ceramic particles may be stirring for 10 hours or more, 15 hours or more, 20 hours or more, or 30 hours or less.

Since the method for manufacturing surface-modified ceramic particles has a temperature in a range of room temperature, it may have excellent processability without high energy consumption in the process.

The method for manufacturing surface-modified ceramic particles may further include filtering a dispersion reacted in the manufacturing of surface-modified ceramic particles and then drying the filtered product to obtain surface-modified ceramic particles. Since the obtaining of surface-modified ceramic particles is a method commonly known in the art, detailed description thereof will be omitted.

As an exemplary embodiment of the present disclosure, the surface-modified ceramic particles may have a modification efficiency calculated by the following Equation 2 of 10% or more, 15% or more, 20% or more, 30% or more, 40% or more, 50% or more, 60% or more, 70% or more, 80% or more, 90% or more, and 92% or more, 95% or more, 96% or more, 97% or more, 98% or more, or 99% or more, and though the upper limit is not limited, 100% or less, and may also be a value within the ranges of the above figures. For example, the modification efficiency may be 10 to 100%, 15 to 100%, 20 to 100%, 30 to 100%, 40 to 100%, 50 to 100%, 60 to 100%, 70 to 100%, 80 to 100%, 90 to 100%, 92 to 100%, 95 to 100%, 96 to 100%, 97 to 100%, 98 to 100%, or 99 to 100%:

$$Modification efficiency ( \% ) = \frac{( {C}_{0} - {C}_{f} ) \times V}{m} \times 100 \qquad [ Equation 2 ]$$

wherein C₀ is an ion concentration (mg/L) of a modifying metal ion precursor in a solution, C_{f} is an ion concentration (mg/L) of a modifying metal ion precursor in a solution, after the manufacturing of surface-modified ceramic particles, V is a volume (L) of a solution, and m is a content (g) of ceramic particles added to the manufacturing of surface-modified ceramic particles.

The method for manufacturing surface-modified ceramic particles may have the modification efficiency of 10% or more, 60% or more, and, in particular, when FeSO₄, CuSO₄, B(OH)₃, ZrOCl₂, and the hydrate thereof are used, the modification may be 98% or more, but the present disclosure is not necessarily limited thereto.

Therefore, the surface-modified ceramic particles are manufactured with excellent processability and excellent productivity and may have excellent miscibility with an epoxy resin by bonding modifying metal ions to the surface of a ceramic particle to increase the zeta potential.

As a result, though the heat dissipating epoxy resin composition may produce a cured product having excellent heat dissipating properties by including an excessive amount of surface-modified ceramic particles, it may have viscosity favorable for workability.

### [Heat Dissipating Epoxy Resin Composition and Cured Product]

As an embodiment of the present disclosure, the heat-dissipating epoxy resin composition comprises, based on 100 parts by weight of epoxy resin, surface-modified ceramic particles in an amount of 10 parts by weight or more, 50 parts by weight or more, 100 parts by weight or more, 150 parts by weight or more, 200 parts by weight or more, 250 parts by weight or more, 300 parts by weight or more, 350 parts by weight or more, 400 parts by weight or more, 450 parts by weight or more, 500 parts by weight or more, 550 parts by weight or more, 600 parts by weight or more, or 800 parts by weight or less, or between these numerical values. For example, the surface-modified ceramic particles may be included at 500 to 800 parts by weight, 100 to 800 parts by weight, 150 to 800 parts by weight, 200 to 800 parts by weight, 250 to 800 parts by weight, 300 to 800 parts by weight, 350 to 800 parts by weight, 400 to 800 parts by weight, 450 to 800 parts by weight, 500 to 800 parts by weight, 550 to 800 parts by weight, or 600 to 800 parts by weight.

Since heat dissipating epoxy resin composition adopts the surface-modified ceramic particles which are modified so as to efficiently improve the zeta potential, as described above, though the composition includes the surface-modified ceramic particles at the content in the range described above, excellent curing behavior, excellent applicability, excellent storage stability, and the like may be maintained.

As an exemplary embodiment of the present disclosure, the heat dissipating epoxy resin composition may have a viscosity measured at 25° C. and a shear rate of 1.0 s−1 of 180 Pa·s or less, 170 Pa·s or less, 160 Pa·s or less, 150 Pa·s or less, 140 Pa·s or less, 130 Pa·s or less, 120 Pa·s or less, 110 Pa·s or less, 100 Pa·s or less, 90 Pa·s or less, 80 Pa·s or less, 70 Pa·s or less, 60 Pa·s or less, 50 Pa·s or less, 40 Pa·s or less and 20 Pa·s or more or 30 Pa·s or more, when 400 parts by weight of the surface-modified ceramic particles are included with respect to 100 parts by weight of the epoxy resin. For example, the viscosity may be 20 to 180 Pa·s, 20 to 170 Pa·s, 20 to 160 Pa·s, 20 to 150 Pa·s, 20 to 140 Pa·s, 20 to 130 Pa·s, 20 to 120 Pa·s, 20 to 110 Pa·s, 20 to 100 Pa·s, 20 to 90 Pa·s, 20 to 80 Pa·s, 20 to 70 Pa·s, 20 to 60 Pa·s, 20 to 50 Pa·s, 20 to 40 Pa·s, or 30 to 40 Pa·s.

The heat dissipating epoxy resin composition may produce a cured product having high thermal conductivity by including the surface-modified ceramic particles in the range described above, and also, though it includes an excessive amount of surface-modified ceramic particles, it may have viscosity favorable for workability.

As an exemplary embodiment of the present disclosure, any epoxy resin may be used without limitation as long as it is an epoxy resin used in the art, and as an example, it may be a one-component epoxy resin including an epoxy compound and a curing agent; or a two-component epoxy resin in which an epoxy compound (main agent) and a curing agent are mixed.

The epoxy compound may be any one or two or more selected from a bisphenol-type epoxy compound, a glycidyl ether-based epoxy compound, a glycidyl amine-based epoxy compound, a phenol novolac-type epoxy compound, a cresol novolac-type epoxy compound, and the like, as a non-limiting example. In addition, the bisphenol-based epoxy compound which is commonly widely used may be any one or two or more selected from a bisphenol A-based epoxy compound, a bisphenol E-based epoxy compound, a bisphenol F-based epoxy compound, a bisphenol M-based epoxy compound, a bisphenol S-based epoxy compound, a bisphenol H-based epoxy compound, and the like, as an example.

The curing agent is not particularly limited as long as it is curable with the epoxy compound described above, and as an example, it may be one or two or more selected from an amine-based curing agent, an amide-based curing agent, a phenol-based curing agent, an acid anhydride-based curing agent, and the like.

The aliphatic amine-based curing agent may be one or two or more selected from diethylenetriamine (DETA), triethylenetetraamine (TETA), tetraethylenepentamine, m-xylenediamine, trimethylhexamethylenediamine, 2-methylpentamethylenediamine, isophoronediamine, 1,3-bisaminomethylcyclohexane, bis(p-aminocyclohexyl) methane (PACM), norbornenediamine, 2,4-diamino-1-methylcyclohexane, 2,6-diamino-1-methylcyclohexane, 1,2-diaminocyclohexane, and the like, as a non-limiting example. The aromatic amine-based curing agent may be one or two or more selected from diaminodiphenylmethane (DDM), m-phenylenediamine, diaminodiphenylsulfone (DDS), 2,4-toluenediamine, 2,6-toluenediamine, diethyltoluenediamine, trimethylenebis(4-aminobenzoate), polytetramethyleneoxide-di-p-aminobenzoate, 2,4-diamino-3,5-diethyltoluene, 2,6-diamino-3,5-diethyltoluene, 1,2-diaminobenzene, 1,3-diaminobenzene, 1,4-diaminobenzene, diaminophenyl oxide, 3,3′,5,5′-tetramethyl-4,4′-diaminobiphenyl, 3,3′-dimethyl-4,4′-diaminodiphenyl, and the like, as a non-limiting example.

The amide-based curing agent may be one or two or more selected from dicyandiamide, a guanidine compound, and an amide-based compound to which an acid anhydride is added, as a non-limiting example. The phenol-based curing agent may be one or two or more selected from a formaldehyde condensation resol type phenol resin, a non-formaldehyde condensation type phenol resin, a novolac-type phenol resin, a novolac-type phenol formaldehyde resin, a polyhydroxystyrene resin, a cresol-type phenol resin, a phenol novolac resin, a cresol novolac resin, a tert-butylphenol novolac resin, a nonylphenol novolac resin, a novolac-type phenol resin, a dicyclopentadiene-modified phenol resin, a terpene-modified phenol resin, a triphenolmethane-type resin, a phenolaralkyl resin, and a special phenol resin (naphtolaralkyl resin; and polyhydroxystyrene resin (poly(p-hydroxystyrene)), and the like as a non-limiting example.

The acid anhydride-based curing agent may be any one or two or more selected from a phthalic anhydride, a maleic anhydride, a trimellitic anhydride, a pyromellitic anhydride, a hexahydrophthalic anhydride, a tetrahydrophthalic anhydride, a methylnadic anhydride, a nadic anhydride, a glutaric anhydride, a methylhexahydrophthalic anhydride, and a methyltetrahydrophthalic anhydride, as a non-limiting example.

In addition to the examples of the epoxy resin and the curing agent described above, any compound may be used without limitation as long as it may be recognized by a person skilled in the art.

As an exemplary embodiment of the present disclosure, the heat dissipating epoxy resin composition may further include 400 parts by weight or less, 300 parts by weight or less, 200 parts by weight, or less, 100 parts by weight or less, 50 parts by weight or less, or 1 part by weight or more of any one or two or more heat dissipating fillers selected from metallic particles, carbonaceous particles, carbon nitrides, and the like, with respect to 100 parts by weight of the epoxy resin.

The metallic particles may be zinc, silicon, tin, boron, antimony, barium, manganese, titanium, calcium, magnesium, vanadium, copper, iron, and a metal oxide thereof, as a non-limiting example. In addition, the carbonaceous particles may include one or two or more selected from single-walled carbon nanotubes, multi-walled carbon nanotubes, graphene, graphite, carbon black, carbon fiber, and fullerene, as a non-limiting example. The nitrogen carbide may include any one or two or more selected from graphitic carbon nitride, carbon nitride, beta carbon nitride, melon, carbon nitride nanotubes, and the like, as a non-limiting example.

The heat dissipating epoxy resin composition further including other heat dissipating fillers described above may have lower viscosity with interchange with the surface-modified ceramic particles, and the cured product manufactured by including the composition may have improved thermal conductivity and improved flexural strength, but the present disclosure is not necessarily limited thereto.

The heat dissipating epoxy resin composition including only the surface-modified ceramic particles may be preferred, since they have low viscosity described above and the cured product manufactured therefrom has improved thermal conductivity and high flexural strength, but the present disclosure is not necessarily limited thereto, as long as the physical properties are not impaired.

The present disclosure provides a heat dissipating cured product manufactured by including the heat dissipating epoxy resin composition.

Since the heat dissipating cured product may include a large amount of the surface-modified ceramic particles with excellent miscibility, it may have high thermal conductivity and excellent mechanical strength.

As an exemplary embodiment of the present disclosure, the heat dissipating cured product may have a thermal conductivity measured at 25° C. of 1.310 W/m·K or more, 1.350 W/m. K or more, 1.400 W/m·K or more, 1.450 W/m·K or more, 1.500 W/m. K or more, 1.550 W/m. K or more, 1.600 W/m·K or more, 1.650 W/m. K or more, 1.700 W/m. K or more, 1.750 W/m·K or more, 1.800 W/m·K or more, 1.850 W/m·K or more, or 2.000 W/m·K or less, when 400 parts by weight of the surface-modified ceramic particles are included with respect to 100 parts by weight of the epoxy resin. For example, the thermal conductivity may be 1.310 to 2.000 W/m·K, 1.350 to 2.000 W/m·K, 1.400 to 2.000 W/m·K, 1.450 to 2.000 W/m·K, 1.500 to 2.000 W/m·K, 1.550 to 2.000 W/m·K, 1.600 to 2.000 W/m·K, 1.650 to 2.000 W/m·K, 1.700 to 2.000 W/m·K, 1.750 to 2.000 W/m·K, 1.800 to 2.000 W/m·K, or 1.850 to 2.000 W/m·K.

As an exemplary embodiment of the present disclosure, the heat dissipating cured product may have a flexural modulus of 4.9 GPa or more, 5.0 GPa or more, 5.5 GPa or more, 6.0 GPa or more, 6.5 GPa or more, or 10.0 GPa or less, when 400 parts by weight of the surface-modified ceramic particles are included with respect to 100 parts by weight of the epoxy resin. For example, the flexural modulus may be 4.9 to 10.0 GPa, 5.0 to 10.0 GPa, 5.5 to 10.0 GPa, 6.0 to 10.0 GPa, or 6.5 to 10.0 GPa.

The heat dissipating epoxy resin composition may have low viscosity favorable for workability even with the inclusion of the surface-modified ceramic particles in an excessive amount of 400 parts by weight of with respect to 100 parts by weight of the epoxy resin, and the heat dissipating cured product manufactured therefrom may have high thermal conductivity and high flexural modulus in the range described above.

The heat dissipating cured product may have another mechanical strength described later.

As an exemplary embodiment of the present disclosure, the heat dissipating cured product may have an effective modulus of 1.80 GPa or more, 1.90 GPa or more, 2.00 GPa or more, 2.10 GPa or more, 2.20 GPa or more, 2.30 GPa or more, 2.40 GPa or more, 2.50 GPa or more, 2.60 GPa or more, 2.70 GPa or more, 2.80 GPa or more, 2.90 GPa or more, 3.00 GPa or more, or 4.00 GPa or less, when 400 parts by weight of the surface-modified ceramic particles are included with respect to 100 parts by weight of the epoxy resin. For example, the effective modulus may be 1.80 to 4.00 GPa, 1.90 to 4.00 GPa, 2.00 to 4.00 GPa, 2.10 to 4.00 GPa, 2.20 to 4.00 GPa, 2.30 to 4.00 GPa, 2.40 to 4.00 GPa, 2.50 to 4.00 GPa, 2.60 to 4.00 GPa, 2.70 to 4.00 GPa, 2.80 to 4.00 GPa, 2.90 to 4.00 GPa, 3.00 to 4.00 GPa.

As an exemplary embodiment of the present disclosure, the heat dissipating cured product may have a tensile modulus of 520 MPa or more, 530 MPa or more, 540 MPa or more, 550 MPa or more, 560 MPa or more, 570 MPa or more, 580 MPa or more, 590 MPa or more, 600 MPa or more, or 700 MPa or less, when 400 parts by weight of the surface-modified ceramic particles are included with respect to 100 parts by weight of the epoxy resin. For example, the tensile modulus may be 530 to 700 MPa, 540 to 700 MPa, 550 to 700 MPa, 560 to 700 MPa, 570 to 700 MPa, 580 to 700 MPa, 590 to 700 MPa, or 600 to 700 MPa.

As an exemplary embodiment of the present disclosure, the heat dissipating cured product may have a flexural energy of 400 J/m² or more, 410 J/m² or more, 420 J/m² or more, 430 J/m² or more, 440 J/m² or more, 450 J/m² or more, 460 J/m² or more, 470 J/m² or more, 480 J/m² or more, 490 J/m² or more, 500 J/m² or more, 510 J/m² or more, 520 J/m² or more, 530 J/m² or more, 540 J/m² or more, 550 J/m² or more, 560 J/m² or more, 570 J/m² or more, 580 J/m² or more, 590 J/m² or more, 600 J/m² or more, or 700 J/m² or less, or may be between the numerical values of the above ranges. For example, the flexural energy may be 400 to 700 J/m², 410 to 700 J/m², 420 to 700 J/m², 430 to 700 J/m², 440 to 700 J/m², 450 to 700 J/m², 460 to 700 J/m², 470 to 700 J/m², 480 to 700 J/m², 490 to 700 J/m², 500 to 700 J/m², 510 to 700 J/m², 520 to 700 J/m², 530 to 700 J/m², 540 to 700 J/m², 550 to 700 J/m², 560 to 700 J/m², 570 to 700 J/m², 580 to 700 J/m², 590 to 700 J/m², or 600 to 700 J/m².

As an exemplary embodiment of the present disclosure, the heat dissipating cured product may have a tensile toughness of 3.00 J/m³ or more, 3.50 J/m³ or more, 4.00 J/m³ or more, 4.50 J/m³ or more, 5.00 J/m³ or more, 5.50 J/m³ or more, 6.00 J/m³ or more, 6.50 J/m³ or more, 7.50 J/m³ or less, or 7.00 J/m³ or less, or may be between the numerical values of the above ranges. For example, the tensile toughness may be 3.00 to 7.50 J/m³, 3.50 to 7.50 J/m³, 4.00 to 7.50 J/m³, 4.50 to 7.50 J/m³, 5.00 to 7.50 J/m³, 5.50 to 7.50 J/m³, 6.00 to 7.50 J/m³, or 6.50 to 7.00 J/m³.

As an exemplary embodiment of the present disclosure, the heat dissipating cured product may have a hardness of 0.070 GPa or more, 0.080 GPa or more, 0.090 GPa or more, 0.100 GPa or more, or 0.150 GPa or less, when 400 parts by weight of the surface-modified ceramic particles are included with respect to 100 parts by weight of the epoxy resin. For example, the flexural modulus may be 0.060 to 0.150 GPa, 0.070 to 0.150 GPa, 0.080 to 0.150 GPa, 0.090 to 0.150 GPa, or 0.100 to 0.150 GPa.

Since the heat dissipating cured product may have high tensile strength and high hardness in addition to the high flexural modulus described above, it may have brittleness and elastic modulus appropriate for electronic devices.

As such, since the heat dissipating epoxy resin composition may have low viscosity favorable for workability even when the surface-modified ceramic particles are included in an excessive amount of 400 parts by weight with respect to 100 parts by weight of the epoxy resin, the heat dissipating cured product formed therefrom may have high thermal conductivity and the excellent mechanical strength described above.

The present disclosure may provide an electronic device including the heat dissipating cured product as an adhesive layer.

The heat dissipating epoxy resin composition may provide viscosity favorable for workability, as described above, and since the heat dissipating cured product manufactured by including the composition has high thermal conductivity, high flexural strength, and excellent thermal dimensional stability, it may be useful as an adhesive of an electronic device, optionally an adhesive which integrates a heat sink and a flexible circuit board of an LED chip. Since the electronic device including the heat dissipating cured product as an adhesive layer may dissipate produced heat excellently, damage due to overheating may be prevented.

As an exemplary embodiment of the present disclosure, the heat dissipating epoxy resin composition is described only for the use of an adhesive of an electronic device, and may be useful as building materials, automotive parts, molds, or the like.

Hereinafter, the present disclosure will be described in more detail by the following examples. However, the following examples are only a reference for describing the present disclosure in detail, and the present disclosure is not limited thereto and may be implemented in various forms. In addition, unless otherwise defined, all technical terms and scientific terms have the same meanings as those commonly understood by a person skilled in the art to which the present disclosure pertains. In addition, the terms used in the present disclosure are only for effectively describing specific examples and are not intended to limit the present disclosure.

### [Measurement Method]

### 1. Field Emission Scanning Electron Microscopy

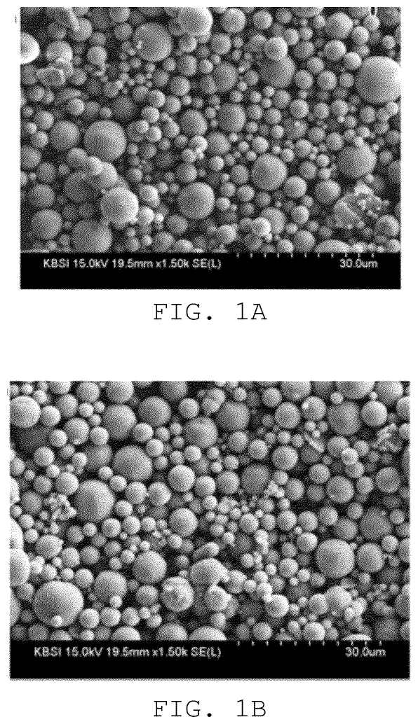

Surface-modified alumina particles (Fe—Al₂O₃) obtained in Example 1 and alumina particles which were not surface modified (r-Al₂O₃) obtained in Comparative Example 1 were photographed using a scanning electron microscope (FE-SEM & EDS, Hitachi, S-4800) and are shown in the following FIGS. 1A and 1B. FIG. 1A is an SEM image of the particles obtained in Comparative Example 1, and FIG. 1B is an SEM image of Fe—Al₂O₃ particles obtained in Preparation Example 1.

### 2. Measurement of Average Particle Diameter

The average particle diameters (D50) of the surface-modified alumina particles manufactured in the example and the alumina particles which were not surface-modified of the comparative example were measured using laser scattering particle size analysis (PSA, Sympatec GmbH, HELOS series).

### 3. Transmission Electron Microscopy and Energy Dispersive X-Ray Spectroscopy

The surface-modified ceramic particles manufactured in Example 1 and the alumina particles which were not surface-modified manufactured in the comparative example were exposed to an electron beam having an electron acceleration of 200 kV, and then photographed with a transmission electron microscope (TEM & EDS, Carl Zeiss, Libra 200 MC TEM) equipped with an energy dispersive spectrometer, and surface electron patterns were measured through EDS.

### 4. Inductively Coupled Plasma Mass Spectrometry Measurement

The surface-modified alumina particles manufactured in the following example and the alumina particles which were not surface-modified of the comparative example were measured with an inductively coupled plasma mass spectrometer (ICP-MS, Agilent 7700), and the contents (ppm) of the included metal elements were determined.

### 5. X-Ray Photoelectron Spectroscopy

The surface-modified alumina particles of Example 1 and the alumina particles of Comparative Preparation Example 1 were analyzed through X-ray photoelectron spectroscopy (XPS) using AXIS high-energy radiation detector (Angle-Resolved X-ray Photoelectron Spectroscopy, AR-XPS, own equipment of Korean Basic Science Institute). In this process, Al Kα (aluminum K alpha) X-ray was used as a light source, and the chemical composition and electron state of the surface of a sample were precisely evaluated.

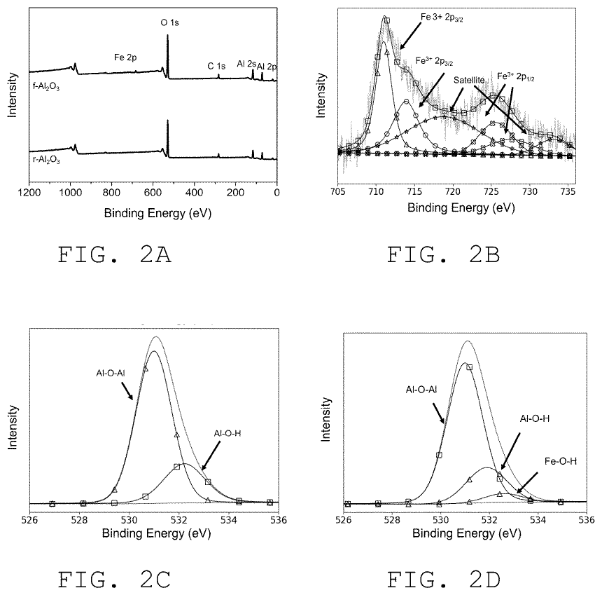

The XPS spectrum of the surface-modified alumina particles of Example 1 and the XPS spectrum of the alumina particles of Comparative Example 1 are shown in FIG. 2A. At this time, an upper line of FIG. 2A is the XPS spectrum of the surface-modified alumina particles of Example 1, and a lower line is the XPS spectrum of the alumina particles of Comparative Example 1. In addition, the Fe2p high resolution XPS spectrum of the surface-modified alumina particles manufactured in Example 1 is shown in FIG. 2B, the O1s high resolution XPS spectrum of the alumina particles of Comparative Example 1 are shown in FIG. 2C, and the O1s high resolution XPS spectrum of the surface-modified ceramic particles manufactured in Example 1 is shown in FIG. 2D.

### 6. Measurement of Zeta Potential

The surface-modified alumina particles manufactured in the example and the alumina particles of comparative example were measured using a Zetasizer (Malvern Instruments, Nano ZS). Specifically, the surface-modified alumina particles and the alumina particles were dispersed in deionized water and sonicated to prepare a suspension having a concentration of 1 mg/ml, the prepared suspension was injected into a folded cell (folded capillary cell), the zeta potential was measured repeatedly a total of 3 times under the condition of pH 7 based on an electrophoretic mobility, and the average value was calculated.

### 7. Measurement of Modification Efficiency

In the following examples, the content (m) of the added alumina particles and the volume (V) of the solution in which a modifying metal ion precursor was dissolved in initial distilled water were measured. Thereafter, in the following example, a concentration (C₀) of a solution in which the modifying metal ion precursor was dissolved in the initial distilled water and a concentration (C_{f}) of a solution in which the modifying metal ion precursor was dissolved in distilled water after manufacturing the surface-modified ceramic particles were measured, and each measured value was calculated by the following Equation 1 to calculate the modification efficiency:

$$Modification efficiency ( \% ) = \frac{( {C}_{0} - {C}_{f} ) \times V}{m} \times 100 \qquad [ Equation l ]$$

### 8. Measurement of Viscosity

The shear rates of the (heat dissipating) epoxy resin compositions manufactured in the example and the comparative example were measured in a shear rate range of 0.1 to 10 s⁻¹, using a rotational shear rheometer (TA, DHR2) under an environment of 25° C., and specifically, the viscosities of the (heat dissipating) epoxy resin compositions measured at shear rates of 1.0 s⁻¹ and 5.0 s⁻¹ were determined.

### 9. Measurement of Thermal Conductivity

Cured products manufactured in the following example and the comparative example were cut into a size of 10 mm×10 mm×2 mm, and a total of 10 measurement samples were manufactured. The densities (ρ, g/cm³) of the manufactured measurement samples were measured using a scale (Sartorius, MSA224S100DU Cubis®) at 25° C., and thermal diffusivities (α, mm2/s) were measured using a laser flash analyzer (Netzsch, LFA 467 HyperFlash®) at −90° C., 25° C., and 100° C. In addition, specific heat (Cp, J/g·K) was determined using an automatic scanning calorimeter (Netzsch, DSC-214 Polyma) at a heating rate of 5° C./min at −90 to 100° C., the measured density, heat diffusivity, and the specific heat were substituted into the following equation to calculate the thermal conductivity (K, W/m·K) to each measurement temperature, and the average thermal conductivity for a total of 10 measurement samples was determined:

$$Thermal conductivity ( κ , W / m \cdot K ) = density ( ρ , g / {cm}^{3} ) \times thermal diffusivity ( α , {mm}^{3} / s ) \times specific heat ( Cp , J / g \cdot K ) . \qquad [ Equation ]$$

### 10. Measurement of Coefficient of Thermal Expansion

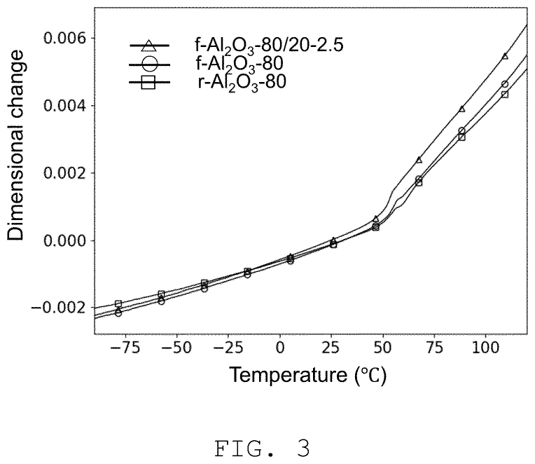

The cured products of Example 14, Example 26, and Comparative Example 3 were cut into a size of 10 mm×10 mm×2 mm to manufacture a total of 10 measurement samples for each cured product. In order to measure the coefficients of linear thermal expansion (CTE, δ) of the measurement samples, a thermodynamic analyzer (Netzsch, TMA402 F1 Hyperion®) was used under an environment of −90 to 120° C., and the results are shown in the following FIG. 3.

### 13. Measurement of Flexural Modulus

The cured products manufactured in the following example and the comparative example were measured in accordance with ASTM D790, and specifically, the cured products were cut into a size of a length of 30 mm, a width of 10 mm, and a thickness of 1 mm, and then the flexural modulus was measured by a 3-point bending flexural strength test using general mechanical measurement equipment (Instron Korea, 34SC-1).

### 14. Measurement of Effective Modulus

The cured products manufactured in the following example and comparative example were cut into a size of a length of 30 mm, a width of 10 mm, and a thickness of 1 mm, and then operated in a three-point bending mode. First, a strain sweep was performed on a strain amplitude range of 0.01 to 0.5% at 25° C. to confirm a linear viscoelastic region (LVR), and the strain in the confirmed LVR was adopted as a test strain. Thereafter, thermal/mechanical equilibrium was secured at a frequency of 1 Hz at 25° C. for 5 minutes or more, and then measurement was performed. A storage modulus E′ was calculated from the load-displacement signal corrected in an equipment software, and an E′ value at 25° C., at 1 Hz, and a selected strain condition was adopted as an “effective modulus”.

### 15. Measurement of Tensile Modulus

The cured products manufactured in the following example and comparative example were subjected to a tensile test with a standard dog-bone-type specimen in accordance with ASTM D638.

### 16. Measurement of Hardness

The cured products manufactured in the following example and comparative example were subjected to a Vickers hardness test in accordance with ASTM E384.

### 17. Measurement of LED Lamp Heat Dissipation Characteristics

Temperature changes in LED lamps manufactured in the following example and comparative example were monitored for 5000 seconds using 3 thermocouples in a constant voltage mode of 8.5 V and 8.5 W provided by a power supply (ED, ED-333E) under the conditions of temperature and humidity controlled, and the temperature at which the average temperature of the heat sink became equilibrium is shown in the following Table 4.

### Manufacture of Surface-Modified Ceramic Particles

### Example 1

20 mg of ferrous sulfate heptahydrate (FeSO₄-7H₂O) was dissolved in 50 ml of distilled water, 100 g of Al₂O₃ particles (Denka, DAW-05) having an average particle diameter (D50) of 5.46 μm was additionally added, and stirring was performed at 25° C. for 24 hours to perform Fe modification on the surface of the Al₂O₃ particles. Thereafter, the dispersion solution which competed stirring was filtered, dried at 80° C. for 48 hours to obtain alumina (Fe—Al₂O₃) particles which were surface-modified with an Fe ion. As a result of measuring the obtained surface-modified alumina (Fe—Al₂O₃) particles by EDS, it was confirmed that the particles had more dominant peaks at 6.404 keV (Kα1) and 7.058 keV (Kβ1), and the iron ion was bonded to the surface.

The obtained surface-modified alumina (Fe—Al₂O₃) particles were measured by the measurement method described above and are shown in the following Table 1.

### Example 2

Alumina (Fe—Al₂O₃) particles which were surface-modified with a Fe ion on the surface were obtained in the same manner as in Example 1, except that ferrous chloride tetrahydrate (FeCl₂-4H₂O) was used instead of ferrous sulfate heptahydrate (FeSO₄-7H₂O).

The obtained surface-modified alumina (Fe—Al₂O₃) particles were measured by the measurement method described above and are shown in the following Table 1.

### Example 3

Alumina (Fe—Al₂O₃) particles which were surface-modified with a Fe ion on the surface were obtained in the same manner as in Example 1, except that ferric chloride hexahydrate (FeCl₃-6H₂O) was used instead of ferrous sulfate heptahydrate (FeSO₄-7H₂O).

The obtained surface-modified alumina (Fe—Al₂O₃) particles were measured by the measurement method described above and are shown in the following Table 1.

### Example 4

Alumina (Fe—Al₂O₃) particles which were surface-modified with a Fe ion on the surface were obtained in the same manner as in Example 1, except that ferric nitrate anhydride (Fe(NO₃)₃-9H₂O) was used instead of ferrous sulfate heptahydrate (FeSO₄-7H₂O).

The obtained surface-modified alumina (Fe—Al₂O₃) particles were measured by the measurement method described above and are shown in the following Table 1.

### Example 5

Alumina (Mn—Al₂O₃) particles which were surface-modified with a Mn ion on the surface were obtained in the same manner as in Example 1, except that manganese sulfate (II) monohydrate (MnSO₄-7H₂O) was used instead of ferrous sulfate heptahydrate (FeSO₄-7H₂O).

The obtained surface-modified alumina (Mn—Al₂O₃) particles were measured by the measurement method described above and are shown in the following Table 1.

### Example 6

Alumina (Co—Al₂O₃) particles which were surface-modified with a Co ion on the surface were obtained in the same manner as in Example 1, except that cobalt sulfate (II) heptahydrate (CoSO₄-7H₂O) was used instead of ferrous sulfate heptahydrate (FeSO₄-7H₂O).

The obtained surface-modified alumina (Co—Al₂O₃) particles were measured by the measurement method described above and are shown in the following Table 1.

### Example 7

Alumina (Ni—Al₂O₃) particles which were surface-modified with a Ni ion on the surface were obtained in the same manner as in Example 1, except that nickel sulfate hexahydrate (NiSO₄-6H₂O) was used instead of ferrous sulfate heptahydrate (FeSO₄-7H₂O).

The obtained surface-modified alumina (Ni—Al₂O₃) particles were measured by the measurement method described above and are shown in the following Table 1.

### Example 8

Alumina (Cu—Al₂O₃) particles which were surface-modified with a Cu ion on the surface were obtained in the same manner as in Example 1, except that copper sulfate (II) pentahydrate (CuSO₄-5H₂O) was used instead of ferrous sulfate heptahydrate (FeSO₄-7H₂O).

The obtained surface-modified alumina (Cu—Al₂O₃) particles were measured by the measurement method described above and are shown in the following Table 1.

### Example 9

Alumina (B—Al₂O₃) particles which were surface-modified with a B ion on the surface were obtained in the same manner as in Example 1, except that boron (III) hydroxide (B(OH)₃) was used instead of ferrous sulfate heptahydrate (FeSO₄-7H₂O).

The obtained surface-modified alumina (B—Al₂O₃) particles were measured by the measurement method described above and are shown in the following Table 1.

### Example 10

Alumina (Zr—Al₂O₃) particles which were surface-modified with a Zr ion on the surface were obtained in the same manner as in Example 1, except that zirconium oxychloride octahydrate (ZrOCl₂-8H₂O) was used instead of ferrous sulfate heptahydrate (FeSO₄-7H₂O).

The obtained surface-modified alumina (Zr—Al₂O₃) particles were measured by the measurement method described above and are shown in the following Table 1.

### Example 11

Alumina (Fe—Al₂O₃) particles which were surface-modified with a Fe ion were obtained in the same manner as in Example 1, except that Al₂O₃ particles having an average particle diameter (D50) of 0.263 μm (Denka, ASFP-20) were used instead of Al₂O₃ particles having an average particle diameter (D50) of 5.46 μm (Denka, DAW-05).

The obtained surface-modified alumina (Fe—Al₂O₃) particles were measured by the measurement method described above and are shown in the following Table 1.

### Example 12

Alumina (Fe—Al₂O₃) particles which were surface-modified with a Fe ion were obtained in the same manner as in Example 1, except that Al₂O₃ particles having an average particle diameter (D50) of 24.6 μm (Denka, DAW-20) were used instead of Al₂O₃ particles having an average particle diameter (D50) of 5.46 μm (Denka, DAW-5).

The obtained surface-modified alumina (Fe—Al₂O₃) particles were measured by the measurement method described above and are shown in the following Table 1.

### Example 13

Alumina (Fe—Al₂O₃) particles which were surface-modified with a Fe ion were obtained in the same manner as in Example 1, except that Al₂O₃ particles having an average particle diameter (D50) of 42.8 μm (Denka, DAW-40) were used instead of Al₂O₃ particles having an average particle diameter (D50) of 5.46 μm (Denka, DAW-5).

The obtained surface-modified alumina (Fe—Al₂O₃) particles were measured by the measurement method described above and are shown in the following Table 1.

### Comparative Example 1

The Al₂O₃ particles having an average particle diameter (D50) of 5.46 μm (Denka, DAW-5) used in Example 1 were measured by the measurement method described above, and the results are shown in the following Table 1.

### Comparative Example 2

The Al₂O₃ particles having an average particle diameter (D50) of 0.263 μm (Denka, ASFP-20) used in Example 11 were measured by the measurement method described above, and the results are shown in the following Table 1.

TABLE 1

| | | | | | |
|---|---|---|---|---|---|
| | Average | Modified | | | |
| Modifying | particle | ion | | Modification | Zeta |
| metal ion | diameter | content | S content | efficiency | potential |
| precursor | (μm) | (ppm) | (ppm) | (%) | (mV) |

Surface modification of Al₂O₃ particles having average particle diameter (D50) of 5.46 μm

| | | | | | | |
|---|---|---|---|---|---|---|
| Comparative | — | 5.46 | 5.2 | 0.1 | — | +38.3 |
| Example 1 | | | | | | |
| Example 1 | FeSO₄ | 5.51 | 39.7 | 0.2 | 98.76 | +45.3 |
| Example 2 | FeCl₂ | 5.50 | 8.10 | 0.1 | 20.15 | +41.4 |
| Example 3 | FeCl₃ | 5.49 | 5.73 | 0.1 | 14.25 | +40.3 |
| Example 4 | Fe(NO₃)₃ | 5.48 | 6.23 | 0.1 | 15.51 | +40.4 |
| Example 5 | MnSO₄ | 5.52 | 23.7 | 0.1 | 60.02 | +38.9 |
| Example 6 | CoSO₄ | 5.50 | 34.6 | 0.2 | 81.65 | +39.3 |
| Example 7 | NiSO₄ | 5.55 | 38.9 | 0.2 | 92.17 | +39.7 |
| Example 8 | CuSO₄ | 5.53 | 45.3 | 0.2 | 98.95 | +39.8 |
| Example 9 | B(OH)₃ | 5.51 | 7.71 | 0.2 | 98.85 | +43.02 |
| Example 10 | ZrOCl₂ | 5.52 | 64.9 | 0.1 | 99.10 | +46.21 |

Surface modification of Al₂O₃ particles having average particle diameter (D50) of 0.2 μm

| | | | | | | |
|---|---|---|---|---|---|---|
| Comparative | — | 0.256 | 39.6 | 0.1 | — | +41.6 |
| Example 2 | | | | | | |
| Example 11 | FeSO₄ | 0.263 | 39.8 | 0.2 | 98.82 | +48.6 |

Surface modification of Al₂O₃ particles having average particle diameter (D50) of 24.6 μm

| | | | | | | |
|---|---|---|---|---|---|---|
| Example 12 | FeSO₄ | 25.1 | 25.1 | 0.2 | 98.54 | +45.1 |

Surface modification of Al₂O₃ particles having average particle diameter (D50) of 42.8 μm

| | | | | | | |
|---|---|---|---|---|---|---|
| Example 13 | FeSO₄ | 43.8 | 43.3 | 0.2 | 98.48 | +42.5 |

In Table 1, it was confirmed that in Examples 1 to 4, the particles had the surface modification efficiency of 10% or more, and the surface-modified ceramic particles of Example 1 using the FeSO₄ hydrate of Example 1 had the modification efficiency of 95% or more.

In Table 1, the surface-modified ceramic particles of Examples 5 to 10 had the modification efficiency of 60% or more, 80% or more, 90% or more, 95% or more, or 98% or more for the modifying metal ion of a manganese, cobalt, nickel, copper, boron, or zirconium ion in addition to the iron ion and was confirmed to allow the surface of the alumina particle to be modified, and in particular, it was confirmed that the surface-modified alumina particles of Examples 9 or 10 in which a boron ion or zirconium ion was modified had the zeta potential of 40 mV or more.

In Table 1, it was confirmed in Example 11 that as the smaller the average particle diameter (D50), the higher the zeta potential of the alumina particles which were not surface-modified, and the particles had a more increased zeta potential by surface modification thereof. In addition, it was confirmed in Examples 12 and 13 that even when the average particle diameter (D50) of the alumina particles was increased, modification with a modification efficiency of 98% or more was allowed.

The surface-modified ceramic particles are described by the drawings below.

Referring to FIG. 1B, it was confirmed that the Fe—Al₂O₃ particles of Example 1 had a uniform spherical shape like the r-Al₂O₃ particles manufactured in Comparative Example 1 of FIG. 1A, even when the surface of the spherical alumina particle was modified with Fe.

Therefore, it was confirmed that the surface-modified ceramic particles according to the present disclosure were able to be uniformly modified with a modifying metal ion only on the surface without a change in the spherical shape, even when the surface was modified with the modifying metal ion.

Referring to FIG. 2A, it was confirmed that the Fe—Al₂O₃ particles manufactured in Example 1 showed O1s, C1s, A12s, and A12p peaks clearly in the XPS spectrum, and showed a new Fe2p peak. In addition, referring to the high resolution XPS spectrum of the Fe2p peak shown in FIG. 2B, it was confirmed that the Fe—Al₂O₃ particles manufactured in Example 1 were clearly modified with an iron atom by various bonds.

In the following FIG. 2D, referring to the O1s high resolution XPS spectrum of the Fe—Al₂O₃ particles manufactured in Example 1, it was confirmed that the Fe—Al₂O₃ particles manufactured in Preparation Example 1 showed a new peak in Fe—O—OH in the 531.0 eV and 531.9 eV peaks.

However, in the following FIG. 2C, referring to the Olas high resolution XPS spectrum of the r-Al₂O₃ particles manufactured in Comparative Example 1, it was confirmed that there was no new peak found at 531.9 eV of the Fe—Al₂O₃ particles of Preparation Example 1.

### Manufacture of Heat Dissipating Epoxy Resin Composition and Heat Dissipating Cured Product

### Example 14

20 wt % of a two-component type epoxy resin in which 3.67 g of a main agent (The Emerson and Cuming Company, Stycast 1266 PTA) and 1.024 g of a crosslinking agent (The Emerson and Cuming Company, Stycast 1266 PTB) were mixed with respect to the total weight of the manufactured heat dissipating epoxy resin composition; and 80 wt % of the Fe—Al₂O₃ particles manufactured in Example 1 were added to a stirrer and stirred for 5 minutes to manufacture a heat dissipating epoxy resin composition. In addition, the heat dissipating epoxy resin composition manufactured above was placed in an oven and cured at 30° C. for 24 hours to manufacture a heat dissipating cured product.

The heat dissipating epoxy resin composition manufactured above and the heat dissipating cured product were measured by the measurement method described above, and the results are shown in the following Tables 2 and 3.

### Example 15

A heat dissipating epoxy composition and a heat dissipating cured product were manufactured in the same manner as in Example 14, except that the Fe—Al₂O₃ particles manufactured in Example 2 were used instead of the Fe—Al₂O₃ particles manufactured in Example 1.

The heat dissipating epoxy resin composition manufactured above and the heat dissipating cured product were measured by the measurement method described above, and the results are shown in the following Tables 2 and 3.

### Example 16

A heat dissipating epoxy composition and a heat dissipating cured product were manufactured in the same manner as in Example 14, except that the Fe—Al₂O₃ particles manufactured in Example 3 were used instead of the Fe—Al₂O₃ particles manufactured in Example 1.

The heat dissipating epoxy resin composition manufactured above and the heat dissipating cured product were measured by the measurement method described above, and the results are shown in the following Tables 2 and 3.

### Example 17

A heat dissipating epoxy composition and a heat dissipating cured product were manufactured in the same manner as in Example 14, except that the Fe—Al₂O₃ particles manufactured in Example 4 were used instead of the Fe—Al₂O₃ particles manufactured in Example 1.

The heat dissipating epoxy resin composition manufactured above and the heat dissipating cured product were measured by the measurement method described above, and the results are shown in the following Tables 2 and 3.

### Example 18

A heat dissipating epoxy composition and a heat dissipating cured product were manufactured in the same manner as in Example 14, except that the Fe—Al₂O₃ particles manufactured in Example 5 were used instead of the Fe—Al₂O₃ particles manufactured in Example 1.

The heat dissipating epoxy resin composition manufactured above and the heat dissipating cured product were measured by the measurement method described above, and the results are shown in the following Tables 2 and 3.

### Example 19

A heat dissipating epoxy composition and a heat dissipating cured product were manufactured in the same manner as in Example 14, except that the Co—Al₂O₃ particles manufactured in Example 6 were used instead of the Fe—Al₂O₃ particles manufactured in Example 1.

The heat dissipating epoxy resin composition manufactured above and the heat dissipating cured product were measured by the measurement method described above, and the results are shown in the following Tables 2 and 3.

### Example 20

A heat dissipating epoxy composition and a heat dissipating cured product were manufactured in the same manner as in Example 14, except that the Ni—Al₂O₃ particles manufactured in Example 7 were used instead of the Fe—Al₂O₃ particles manufactured in Example 1.

The heat dissipating epoxy resin composition manufactured above and the heat dissipating cured product were measured by the measurement method described above, and the results are shown in the following Tables 2 and 3.

### Example 21

A heat dissipating epoxy composition and a heat dissipating cured product were manufactured in the same manner as in Example 14, except that the Cu—Al₂O₃ particles manufactured in Example 8 were used instead of the Fe—Al₂O₃ particles manufactured in Example 1.

The heat dissipating epoxy resin composition manufactured above and the heat dissipating cured product were measured by the measurement method described above, and the results are shown in the following Tables 2 and 3.

### Example 22

A heat dissipating epoxy composition and a heat dissipating cured product were manufactured in the same manner as in Example 14, except that the B—Al₂O₃ particles manufactured in Example 9 were used instead of the Fe—Al₂O₃ particles manufactured in Example 1.

The heat dissipating epoxy resin composition manufactured above and the heat dissipating cured product were measured by the measurement method described above, and the results are shown in the following Tables 2 and 3.

### Example 23

A heat dissipating epoxy composition and a heat dissipating cured product were manufactured in the same manner as in Example 14, except that the Zr—Al₂O₃ particles manufactured in Example 10 were used instead of the Fe—Al₂O₃ particles manufactured in Example 1.

The heat dissipating epoxy resin composition manufactured above and the heat dissipating cured product were measured by the measurement method described above, and the results are shown in the following Tables 2 and 3.

### Example 24

A heat dissipating epoxy composition and a heat dissipating cured product were manufactured in the same manner as in Example 14, except that the Fe—Al₂O₃ particles manufactured in Example 11 were used instead of the Fe—Al₂O₃ particles manufactured in Example 1.

The heat dissipating epoxy resin composition manufactured above and the heat dissipating cured product were measured by the measurement method described above, and the results are shown in the following Tables 2 and 3.

### Example 25

A heat dissipating epoxy composition and a heat dissipating cured product were manufactured in the same manner as in Example 14, except that the Fe—Al₂O₃ particles manufactured in Example 1 were added at 82.5 wt % with respect to the total weight of the heat dissipating epoxy.

The heat dissipating epoxy resin composition manufactured above and the heat dissipating cured product were measured by the measurement method described above, and the results are shown in the following Tables 2 and 3.

### Example 26

A heat dissipating epoxy composition and a heat dissipating cured product were manufactured in the same manner as in Example 14, except that 80.0 wt % of the Fe—Al₂O₃ particles manufactured in Example 1 (average particle diameter: 5.46 μm) and 2.5 wt % of Fe—Al₂O₃ particles manufactured in Example 12 (average particle diameter: 25.1 μm) were added with respect to the total weight of the heat dissipating epoxy.

The heat dissipating epoxy resin composition manufactured above and the heat dissipating cured product were measured by the measurement method described above, and the results are shown in the following Tables 2 and 3.

### Example 27

A heat dissipating epoxy composition and a heat dissipating cured product were manufactured in the same manner as in Example 14, except that 80.0 wt % of the Fe—Al₂O₃ particles manufactured in Example 1 (average particle diameter: 5.46 μm) and 2.5 wt % of Fe—Al₂O₃ particles manufactured in Example 13 (average particle diameter: 43.8 μm) were added with respect to the total weight of the heat dissipating epoxy.

The heat dissipating epoxy resin composition manufactured above and the heat dissipating cured product were measured by the measurement method described above, and the results are shown in the following Tables 2 and 3.

### Comparative Example 3

A heat dissipating epoxy composition and a heat dissipating cured product were manufactured in the same manner as in Example 14, except that the alumina (r-Al₂O₃) particles which were not surface-modified of Comparative Example 1 were used instead of the Fe—Al₂O₃ particles manufactured in Example 1.

The heat dissipating epoxy resin composition manufactured above and the heat dissipating cured product were measured by the measurement method described above, and the results are shown in the following Tables 2 and 3.

### Comparative Example 4

A heat dissipating epoxy composition and a heat dissipating cured product were manufactured in the same manner as in Example 25, except that the alumina (r-Al₂O₃) particles which were not surface-modified of Comparative Example 1 were used instead of the Fe—Al₂O₃ particles manufactured in Example 1.

The heat dissipating epoxy resin composition manufactured above and the heat dissipating cured product were measured by the measurement method described above, and the results are shown in the following Tables 2 and 3.

### Comparative Example 5

A heat dissipating epoxy composition and a heat dissipating cured product were manufactured in the same manner as in Example 14, except that the alumina (r-Al₂O₃) particles which were not surface-modified of Comparative Example 2 were used instead of the Fe—Al₂O₃ particles manufactured in Example 1.

The heat dissipating epoxy resin composition manufactured above and the heat dissipating cured product were measured by the measurement method described above, and the results are shown in the following Tables 2 and 3.

### Comparative Example 6

The process was performed in the same manner as in Example 14, except that the Fe—Al₂O₃ particles manufactured in Example 1 were not included and 100 wt % of a two-component type epoxy resin in which 3.67 g of a main agent (The Emerson and Cuming Company, Stycast 1266 PTA) and 1.024 g of a crosslinking agent (The Emerson and Cuming Company, Stycast 1266 PTB) were mixed was used, and the cured product therefrom was manufactured.

The epoxy resin and the cured product manufactured above were measured by the measurement method described above, and the results are shown in the following Tables 2 and 3.

TABLE 2

| | | | First surface-modified alumina | | | Second surface-modified alumina | | | | |
|---|---|---|---|---|---|---|---|---|---|---|
| | | Epoxy | particles | | | particles | | | | |
| | | resin | | Particle | | | Particle | | Viscosity | |
| | | Content | | diameter | Content | | diameter | Content | Viscosity | Viscosity |
| | | (wt %) | Type | (μm) | (wt %) | Type | (μm) | (wt %) | of 1.0 s⁻¹ | of 5.0 s⁻¹ |
| Example | 14 | 20 | Example 1 | 5.51 | 80 | Not included | | | 33.47 | 10.76 |
| | 15 | 20 | Example 2 | 5.50 | 80 | Not included | | | 145.35 | 72.26 |
| | 16 | 20 | Example 3 | 5.49 | 80 | Not included | | | 148.21 | 73.11 |
| | 17 | 20 | Example 4 | 5.48 | 80 | Not included | | | 148.55 | 73.15 |
| | 18 | 20 | Example 5 | 5.52 | 80 | Not included | | | 150.24 | 73.32 |
| | 19 | 20 | Example 6 | 5.50 | 80 | Not included | | | 148.55 | 73.46 |
| | 20 | 20 | Example 7 | 5.55 | 80 | Not included | | | 148.29 | 73.41 |
| | 21 | 20 | Example 8 | 5.53 | 80 | Not included | | | 147.72 | 73.24 |
| | 22 | 20 | Example 9 | 5.52 | 80 | Not included | | | 33.87 | 9.57 |
| | 23 | 20 | Example 10 | 5.52 | 80 | Not included | | | 33.21 | 9.97 |
| | 24 | 20 | Example 11 | 0.263 | 80 | Not included | | | 31.51 | 9.15 |
| | 25 | 17.5 | Example 1 | 0.51 | 82.5 | Not included | | | 107.12 | 61.34 |
| | 26 | 17.5 | Example 1 | 5.51 | 80 | Example 12 | 25.1 | 2.5 | 87.10 | 45.54 |
| | 27 | 17.5 | Example 1 | 5.51 | 80 | Example 13 | 43.3 | 2.5 | 176.77 | 105.10 |

| | | | | | | | | |
|---|---|---|---|---|---|---|---|---|
| Comparative | 3 | 20 | Comparative | 5.46 | 80 | Not included | 107.12 | 73.59 |

Example 1

| | | | | | | | |
|---|---|---|---|---|---|---|---|
| 4 | 17.5 | Comparative | 5.46 | 82.5 | Not included | Immeasurable | Immeasurable |

Example 1

| | | | | | | | |
|---|---|---|---|---|---|---|---|
| 5 | 20 | Comparative | 5.46 | 80 | Not included | 150.12 | 72.52 |

Example 2

| | | | | |
|---|---|---|---|---|
| 6 | 100 | Not included | 2.15 | 0.69 |

TABLE 3

| | | | | | Mechanical strength | | | |
|---|---|---|---|---|---|---|---|---|
| | | Thermal conductivity | | | Flexural | Effective | Tensile | |
| | | −90° C. | 25° C. | 100° C. | modulus | modulus | modulus | Hardness |
| unit | | W/m · K | | | GPa | GPa | MPa | GPa |
| Example | 14 | 1.098 | 1.441 | 1.257 | 5.33 | 2.180 | 588.68 | 0.082 |
| | 15 | 0.923 | 1.318 | 1.089 | 4.95 | 1.914 | 525.75 | 0.074 |
| | 16 | 0.922 | 1.313 | 1.089 | 4.96 | 1.916 | 528.38 | 0.078 |
| | 17 | 0.915 | 1.310 | 1.086 | 4.94 | 1.900 | 535.96 | 0.079 |
| | 18 | 0.920 | 1.311 | 1.087 | 4.93 | 1.886 | 531.21 | 0.078 |
| | 19 | 0.921 | 1.315 | 1.089 | 4.90 | 1.890 | 533.37 | 0.077 |
| | 20 | 0.923 | 1.317 | 1.090 | 4.91 | 1.878 | 525.89 | 0.079 |
| | 21 | 0.927 | 1.320 | 1.096 | 4.96 | 1.894 | 532.90 | 0.078 |
| | 22 | 1.095 | 1.441 | 1.256 | 5.30 | 2.174 | 586.92 | 0.084 |
| | 23 | 1.052 | 1.423 | 1.208 | 5.27 | 2.140 | 581.87 | 0.081 |
| | 24 | 1.130 | 1.489 | 1.364 | 5.47 | 2.224 | 596.44 | 0.087 |
| | 25 | 1.056 | 1.424 | 1.209 | 5.21 | 2.16 | 585.83 | 0.082 |
| | 26 | 1.692 | 1.898 | 1.649 | 6.49 | 2.260 | 612.06 | 0.109 |
| | 27 | 1.582 | 1.823 | 1.589 | 6.11 | 2.25 | 601.21 | 0.105 |
| Comparative | 3 | 0.915 | 1.304 | 1.084 | 4.94 | 1.88 | 517.48 | 0.077 |
| Example | 4 | Immeasurable | Immeasurable | Immeasurable | Immeasurable | Immeasurable | Immeasurable | Immeasurable |
| | 5 | 0.802 | 1.207 | 0.947 | 4.785 | 1.78 | 506.80 | 0.069 |
| | 6 | 0.306 | 0.352 | 0.337 | 1.35 | 0.36 | 130.03 | 0.019 |

In Table 2, it was confirmed that the heat dissipating epoxy resin compositions of Examples 14 to 27 had a low viscosity measured at 25° C. and a shear rate of 1.0 s−1 of 180 Pa·s or less, 150 Pa·s or less, 140 Pa·s or less, 130 Pa·s or less, 50 Pa·s or less, or 40 Pa·s or less. This suggests that as the zeta potential of the surface-modified ceramic particles included in the heat dissipating epoxy resin composition was higher, the particles may be included at 400 parts by weight without a rapid increase of viscosity.

In Table 3, since the heat dissipating cured products of Examples 14 to 17 were able to include an excessive amount of surface-modified alumina particles with excellent miscibility, it was confirmed that they had a thermal conductivity at 25° C. of 1.310 W/m·K or more, 1.400 W/m·K or more, 1.500 W/m·K or more, or 1.800 W/m·K or more.

Therefore, the heat dissipating epoxy resin compositions of Examples 14 to 17 had a viscosity which was not greatly increased even when an excessive amount of the surface-modified ceramic particles was included, or optionally rather had a decreased viscosity, and produced a cured product having an increased thermal conductivity by including the composition.

In Table 2, since the heat dissipating epoxy resin composition included a large amount of surface-modified ceramic particles with excellent miscibility, it was confirmed that the heat dissipating cured product formed by including the composition had increased mechanical strength as compared with the cured product of Comparative Example 1.

However, in Tables 2 and 3, it was confirmed that the cured product of Comparative Example 3 including the alumina particles which were not surface-modified had a thermal conductivity for securing a heat dissipation effect of less than 1.310 W/m·K, and also, when it included the alumina particles in a more excessive amount, like the epoxy composition of Comparative Example 4, the viscosity was increased to a degree where operation was not allowed.

In addition, when the epoxy resin composition of Comparative Example 5 included 80 wt % or more of unmodified alumina particles having an average particle diameter of about 0.2 μm, the composition had a lowered thermal conductivity and had a similar value to the thermal conductivity of the cured product of Comparative Example 6.

Referring to the following FIG. 3, the heat dissipating cured products manufactured in Example 14 and 36 did not show a large difference between the coefficient of thermal expansion (CTE) at a temperature before the glass transition temperature of about 50° C. and the coefficient of thermal expansion (CTE) at a temperature after the glass transition temperature, but the cured product of Comparative Example 3 showed a great change in the coefficients of thermal expansion (CTE) before the glass transition temperature and after the glass transition temperature.

### Manufacture of LED Lamp

### Example 28

The heat dissipating epoxy resin composition of Example 14 was evenly applied at 0.5 mm on a heat sink manufactured with aluminum and then adhered to a printed circuit board (PCB) packaging 16 yellow LED chips (Samsung Electronics, LM283B+) to manufacture a LED lamp. 3 thermocouples were attached to the back side of the manufactured LED lamp and each thermocouple was labeled as channel 1, channel 2, and channel 3.

Thereafter, the manufactured LED lamp was measured by the measurement method described above, and the results are shown in the following Table 4.

### Example 29

An LED lamp was manufactured in the same manner as in Example 28, except that the heat dissipating epoxy resin composition of Example 26 was used instead of the heat dissipating epoxy resin composition of Example 14.

Thereafter, the manufactured LED lamp was measured by the measurement method described above, and the results are shown in the following Table 4.

### Comparative Example 7

An LED lamp was manufactured in the same manner as in Example 28, except that the heat dissipating epoxy resin composition of Comparative Example 3 was used instead of the heat dissipating epoxy resin composition of Example 14.

Thereafter, the manufactured LED lamp was measured by the measurement method described above, and the results are shown in the following Table 4.

### Comparative Example 8

An LED lamp was manufactured in the same manner as in Example 28, except that the heat dissipating epoxy resin composition of Comparative Example 6 was used instead of the heat dissipating epoxy resin composition of Example 14.

Thereafter, the manufactured LED lamp was measured by the measurement method described above, and the results are shown in the following Table 4.

TABLE 4

| | Equilibrium |
|---|---|
| | temperature |
| | (° C.) |
| Example 28 | 71.14 |
| Example 29 | 75.91 |
| Comparative | 68.54 |
| Example 7 | |
| Comparative | 65.15 |
| Example 8 | |

Referring to Examples 28 and 29 in Table 4, it was confirmed that the heat sink attached from the heat dissipating epoxy composition had an equilibrium temperature of 70° C. or higher, and continuously dissipated heat produced in LED through the heat sink.

However, it was confirmed that the LED lamps of Comparative Examples 7 and 8 had the equilibrium temperature of the heat sink of lower than 70° C. and had low heat dissipating properties than the examples.

Although the exemplary embodiments of the present disclosure have been described above, the present disclosure is not limited to the exemplary embodiments but may be made in various forms different from each other, and those skilled in the art will understand that the present disclosure may be implemented in other specific forms without departing from the technical spirit or the essential feature of the present disclosure. Therefore, it should be understood that the exemplary embodiments described above are not restrictive, but illustrative in all aspects.

1. A surface-modified ceramic particle comprising:
a ceramic particle; and
a modifying metal ion bonded to a surface of the ceramic particle.

2. The surface-modified ceramic particle of claim 1, wherein the surface-modified ceramic particle has a modifying metal bonded to the surface of the ceramic particle by a coordinate bond.

3. The surface-modified ceramic particle of claim 1, wherein the surface-modified ceramic particles have an average particle diameter (D50) of 0.1 to 100 μm.

4. The surface-modified ceramic particle of claim 3, wherein the surface-modified ceramic particles satisfy 0.1 μm≤average particle diameter (D50)<1.0 μm and have a zeta potential measured in a suspension state at 1 mg/ml and pH 7 of 40.0 mV or more.

5. The surface-modified ceramic particle of claim 3, wherein the surface-modified ceramic particles satisfy 1.5 μm<average particle diameter (D50)≤100 μm and have a zeta potential measured in a suspension state at 1 mg/ml and pH 7 of more than 38.0 mV.

6. The surface-modified ceramic particle of claim 1, wherein the modifying metal ion is any one or two or more cations selected from manganese (Mn), cobalt (Co), nickel (Ni), copper (Cu), iron (Fe), boron (B), and zirconium (Zr).

7. The surface-modified ceramic particle of claim 1, wherein the ceramic particle is an aluminum oxide particle.

8. The surface-modified ceramic particle of claim 1, wherein the surface-modified ceramic particle includes 5 to 100 ppm of the modifying metal ion.

9. A heat dissipating epoxy resin composition comprising:
an epoxy resin; and
the surface-modified ceramic particle of claim 1.

10. The heat dissipating epoxy resin composition of claim 9, wherein the heat dissipating epoxy resin composition includes 10 to 800 parts by weight of the surface-modified ceramic particles with respect to 100 parts by weight of the epoxy resin.

11. The heat dissipating epoxy resin composition of claim 9, wherein the surface-modified ceramic particles have a multimodal particle diameter distribution.

12. The heat dissipating epoxy resin composition of claim 9, wherein the heat dissipating epoxy resin composition has a viscosity measured at 25° C. and a shear rate of 1.0 s⁻¹ of 180 Pa·s or less, when 400 parts by weight of the surface-modified ceramic particles are included with respect to 100 parts by weight of the epoxy resin.

13. A heat dissipating cured product manufactured by including the heat dissipating epoxy resin composition of claim 9.

14. The heat dissipating cured product of claim 13, wherein the heat dissipating cured product has a thermal conductivity measured at 25° C. of 1.310 W/m·K or more, when 400 parts by weight of the surface-modified ceramic particles are included with respect to 100 parts by weight of the epoxy resin.

15. The heat dissipating cured product of claim 13, wherein the heat dissipating cured product has a flexural modulus of 4.90 GPa or more, when 400 parts by weight of the surface-modified ceramic particles are included with respect to 100 parts by weight of the epoxy resin.

16. An electronic device comprising the heat dissipating cured product of claim 13.

17. A method for manufacturing surface-modified ceramic particles, the method comprising:
including a modifying metal ion precursor in a solvent to prepare a solution; and
including the solution and ceramic particles to manufacture surface-modified ceramic particles.

18. The method for manufacturing surface-modified ceramic particles of claim 17, wherein the modifying metal ion precursor is any one or two or more selected from metal salts including manganese (Mn), titanium (Ti), silicon (Si), cobalt (Co), nickel (Ni), copper (Cu), iron (Fe), boron (B), or zirconium and metal salt hydrates thereof.

19. The method for manufacturing surface-modified ceramic particles of claim 17, wherein the manufacturing of surface-modified ceramic particles is performed at a reaction temperature of 10 to 50° C.

20. The method for manufacturing surface-modified ceramic particles of claim 17, wherein the surface-modified ceramic particles have a modification efficiency calculated by the following Equation 1 of 10% or more:
$$Modification efficiency ( \% ) = \frac{( {C}_{0} - {C}_{f} ) \times V}{m} \times 100 \qquad [ Equation l ]$$
wherein
C₀ is an ion concentration (mg/L) of a modifying metal ion precursor in a solution,
C_{f} is an ion concentration (mg/L) of a modifying metal ion precursor in a solution, after the manufacturing of surface-modified ceramic particles,
V is a volume (V) of a solution, and
m is a content (g) of ceramic particles added to the manufacturing of surface-modified ceramic particles.
